(19) United States
(12) Patent Application Publication
(10) Pub. No.: US 2010/0237250 A1
(43) Pub. Date: Sep. 23, 2010

(54) PHOTOSENSOR AND METHOD OF MANUFACTURING THE SAME

(75) Inventor: Masami HAYASHI, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/724,878

(22) Filed: Mar. 16, 2010

(30) Foreign Application Priority Data
Mar. 23, 2009 (JP) 2009-069681

(51) Int. Cl. H01L 27/144; H01L 31/18; G01T 1/20; H01L 31/101

(52) U.S. Cl. 250/361 R; 438/98; 250/214.1; 257/461; 257/E31.032; 257/E31.126; 257/E31.054

(57) ABSTRACT

A photosensor includes a photodiode including a semiconductor layer. The semiconductor layer is made up of an n-type semiconductor layer, an i-type semiconductor layer and a p-type semiconductor layer, for example. The photosensor further includes a transparent electrode made of a transparent conductive film, and a nitrogen-containing semiconductor layer formed between the semiconductor layer and the transparent electrode.

### INCORPORATION BY REFERENCE

This application is based upon and claims the benefit of priority from Japanese patent application No. 2009-069681, filed on Mar. 23, 2009, the disclosure of which is incorporated herein in its entirety by reference.

### BACKGROUND OF THE INVENTION

1. Field of the Invention

The present invention relates to a photosensor and a method of manufacturing the same.

2. Description of Related Art

A photosensor is a flat panel that includes a TFT array substrate on which a photodiode for photoelectric conversion of visible light and a TFT are formed. The photosensor is widely applied to a contact image sensor, an X-ray imaging display device or the like. Particularly, a flat panel X-ray imaging display device (which is referred to hereinafter as FPD) in which a scintillator for converting X rays into visible light is mounted on a TFT array substrate is a device having a potential for application to the medical industry or the like.

In the field of X-ray image diagnosis, precision images (still images) and real-time image viewing (moving images) are both used. An X-ray film is still mainly used for taking still images. On the other hand, an image pickup tube (image intensifier) that combines a photomultiplier tube and a CCD is used for taking moving images. While the X-ray film has a high spatial resolution, it has a low film speed and can take only still images. The X-ray film further has a disadvantage that development is necessary after picture taking, causing the lack of immediacy. On the other hand, while the image pickup tube has a high film speed and is thus capable of taking moving images, it has a low spatial resolution. The image pickup tube further has a disadvantage that there is a limitation to upsizing because of being a vacuum device.

There are two major FPD architectures: indirect conversion FPD that converts X rays into light by a scintillator such as CsI and then converts light into charge by a photodiode, and direct conversion FPD that directly converts X rays into charge by an X-ray sensor such as Se. The indirect conversion FPD has higher quantum efficiency and a better signal-to-noise ratio (S/N ratio) and enables fluoroscopic imaging with small radiation doses. A structure and a manufacturing method of an array substrate of the indirect conversion FPD are disclosed in related art (cf. e.g. Japanese Unexamined Patent Application Publication No. 2000-101920).

In the array substrate of the FPD, formation of a photodiode which affects photosensor sensitivity, noise or the like is important. A photosensor is made up of an amorphous silicon layer and a transparent conductive film formed on an electrode, as disclosed in Japanese Unexamined Patent Application Publication No. 2000-101920, for example. In the case of using ITO which is commonly used as the transparent conductive film, In is diffused into silicon. This causes that rectification between the i-layer and the p-layer is likely to be lost when a higher bias voltage is applied, which leads to an increase in leakage current of the photodiode.

In light of the foregoing, it is desirable to provide a photosensor and a method of manufacturing the same that suppress an increase in leakage current.

### SUMMARY OF THE INVENTION

A first exemplary aspect of the present invention is a photosensor that includes a photodiode including a semiconductor layer, a photodiode electrode made of a transparent conductive film, and an anti-diffusion layer formed between the semiconductor layer and the photodiode electrode.

A second exemplary aspect of the present invention is a method of manufacturing a photosensor that includes steps of depositing a semiconductor layer constituting a photodiode, and depositing a transparent conductive film used for forming a photodiode electrode placed opposite to the semiconductor layer with an anti-diffusion layer interposed therebetween.

According to the exemplary aspects of the present invention described above, it is possible to provide a photosensor and a method of manufacturing the same that suppress an increase in leakage current

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a schematic view showing a structure of an X-ray imaging device according to a first exemplary embodiment;

FIG. 2 is a plan view showing a structure of a TFT substrate according to the first exemplary embodiment;

FIG. 3 is a plan view showing a structure of a pixel of the TFT substrate according to the first exemplary embodiment;

FIG. 4 is a sectional view along line IV-IV in FIG. 3;

FIG. 5 is a sectional view showing a structure of a terminal part of the TFT substrate according to the first exemplary embodiment;

FIG. 6 is a sectional view showing another structure of a terminal part of the TFT substrate according to the first exemplary embodiment;

FIG. 7 is a sectional view showing a structure of the TFT substrate used in the X-ray imaging device according to the first exemplary embodiment;

FIGS. 8A to 8F are sectional views showing a manufacturing process of the TFT substrate in a pixel according to the first exemplary embodiment;

FIGS. 9A to 9E are sectional views showing a manufacturing process of the TFT substrate in a terminal part according to the first exemplary embodiment;

FIG. 10 is a sectional view showing a structure of a TFT substrate according to a second exemplary embodiment;

FIG. 11 is a sectional view showing a structure of a TFT substrate according to a third exemplary embodiment;

FIGS. 12A to 12B are sectional views showing a manufacturing method of the TFT substrate according to the third exemplary embodiment;

FIG. 13 is a plan view showing a structure of a pixel of a TFT substrate according to a fourth exemplary embodiment; and

FIG. 14 is a plan view showing another structure of a pixel of the TFT substrate according to the fourth exemplary embodiment.

### DESCRIPTION OF THE EXEMPLARY EMBODIMENTS

### First Exemplary Embodiment

An exemplary embodiment of the present invention is described hereinafter with reference to the drawings. A photosensor according to the exemplary embodiment is used in an X-ray imaging device, for example. Referring first to FIG. 1, an X-ray imaging device is described. FIG. 1 is a schematic view showing a structure of an X-ray imaging device.

Referring to FIG. 1, an X-ray imaging device includes an image processing device 200, a photosensor 201 and an X-ray source 202. The photosensor 201, which is a flat panel, and the X-ray source 202 are placed opposite to each other. The photosensor 201 outputs a signal depending on the intensity of incident light. The photosensor 201 includes a scintillator that converts X rays into visible light. The photosensor 201 is connected to the image processing device 200. The image processing device 200 is an information processing device such as a personal computer. The image processing device 200 performs predetermined processing on outputs from the photosensor 201. A display is mounted on the image processing device 200, and an X-ray radiographic image is displayed on the display.

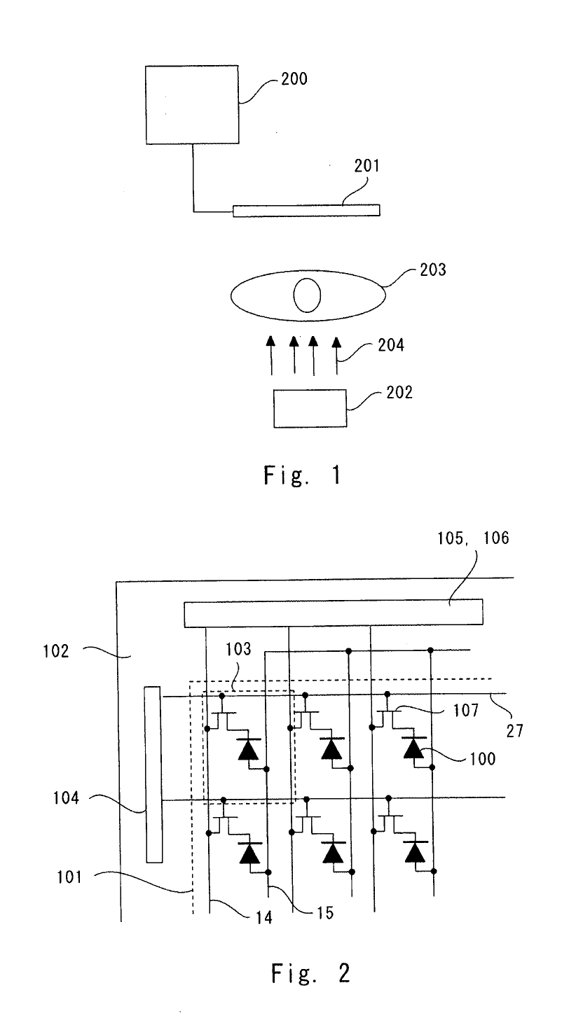

Referring next to FIG. 2, a TFT substrate included in the photosensor 201 according to the exemplary embodiment is described. FIG. 2 is a plan view showing a structure of the TFT substrate.

The TFT substrate is an active matrix TFT array substrate in which a photodiode 100 and a thin film transistor (TFT) 107 are arranged in matrix, for example. The TFT substrate includes a detection area 101 and a frame area 102 surrounding the detection area 101. In the detection area 101, a plurality of gate lines 27, a plurality of data lines 14, and a plurality of bias lines 15 are formed.

The plurality of gate lines 27 are arranged in parallel. The plurality of data lines 14 and the plurality of bias lines 15 are arranged in parallel. The bias lines 15 are respectively arranged between the adjacent data lines 14. Thus, the data lines 14 and the bias lines 15 are arranged alternately with each other. The gate lines 27 and the data lines 14 intersect with each other. Likewise, the gate lines 27 and the bias lines 15 intersect with each other. Further, the gate lines 27 and the data lines 14 are orthogonal to each other. Likewise, the gate lines 27 and the bias lines 15 are orthogonal to each other. An area surrounded by the adjacent gate lines 27 and the adjacent data lines 14 serves as a pixel 103. In the TFT substrate, pixels 103 are arranged in matrix.

Further, in the frame area 102 of the TFT substrate, a gate driving circuit 104, a digital circuit 105 and a charge reading circuit 106 are placed. The gate lines 27 extend from the detection area 101 to the frame area 102. The gate lines 27 are then connected to the gate driving circuit 104 at the end of the TFT substrate. The data lines 14 also extend from the detection area 101 to the frame area 102. The data lines 14 are then electrically connected to the charge reading circuit 106 at the end of the TFT substrate through a low noise amplifier. The digital circuit 105 is electrically connected to the charge reading circuit 106. The low noise amplifier may be placed between the charge reading circuit 106 and the digital circuit 105.

The gate driving circuit 104 is provided with various kinds of external signals through a wiring board, for example. Based on an external control signal, the gate driving circuit 104 supplies a gate signal (scanning signal) to the gate lines 27. By the gate signal, the gate lines 27 are sequentially selected. Outputs from the data lines 14 are supplied to the low noise amplifier and amplified. The amplified signal is supplied to the charge reading circuit 106. The charge reading circuit 106 includes an integration circuit, a sample-and-hold circuit and a multiplexer amplifier, for example. The charge reading circuit 106 reads outputs from the data lines 14. Specifically, the charge reading circuit 106 sequentially selects outputs from the plurality of data lines 14 and transmits them to the digital circuit 105.

The digital circuit 105 at least includes an A/D converter. The digital circuit 105 may further include a correction arithmetic circuit, a conversion circuit or the like. The digital circuit 105 converts the signal from the charge reading circuit 106 from analog to digital by the A/D converter. Then, correction operation is performed by the correction arithmetic circuit on the signal converted from analog to digital. The correction operation may be performed in the image processing device 200. Further, the signal converted from analog to digital is converted by the conversion circuit into a signal conforming to the format for transmission to the image processing device 200 for the purpose of reducing the number of output signals and so on. The gate driving circuit 104, the digital circuit 105 and the charge reading circuit 106 are not necessarily placed on the TFT substrate.

In the pixel 103, one TFT 107 and one photodiode 100 are formed. In the pixel 103, the TFT 107 and the photodiode 100 are connected in series. The TFT 107 is placed near the intersection between the gate line 27 and the data line 14. The TFT 107 serves as a switching element for supplying an output from the photodiode 100 to the data line 14.

A gate electrode of the TFT 107 is connected to the gate line 27, and ON and OFF of the TFT 107 are controlled by a gate signal input from a gate terminal. A source electrode of the TFT 107 is connected to the data line 14. A drain electrode of the TFT 107 is connected to the photodiode 100. When a voltage is applied to the gate electrode and the TFT 107 is turned ON, a current flows from the drain electrode to the source electrode. Thus, charge converted by the photodiode 100 flows to the data line 14 through the TFT 107. The charge from the data line 14 passes through the charge reading circuit 106 or the like and is converted from analog to digital by the digital circuit 105. The TFT substrate has the above-described structure.

When performing X-ray imaging, a test subject 203 is placed between the photosensor 201 and the X-ray source 202. Then, X rays 204 are emitted from the X-ray source 202 toward the test subject 203. The X rays 204 having passed through the test subject 203 are converted into visible light by the scintillator of the photosensor 201. The visible light is then input to the photodiode 100 and photoelectrically converted. Then, charge converted by the photodiode 100 flows to the data line 14 through the TFT 107. The charge from the data line 14 is supplied to the low noise amplifier and amplified. The amplified signal passes through the charge reading circuit 106 and is then converted from analog to digital by the digital circuit 105. Then, the signal converted into a specific format by the conversion circuit after A/D conversion is sequentially transmitted to the image processing device 200. The image processing device 200 performs predetermined processing based on the input signal. An X-ray radiographic image is thereby obtained.

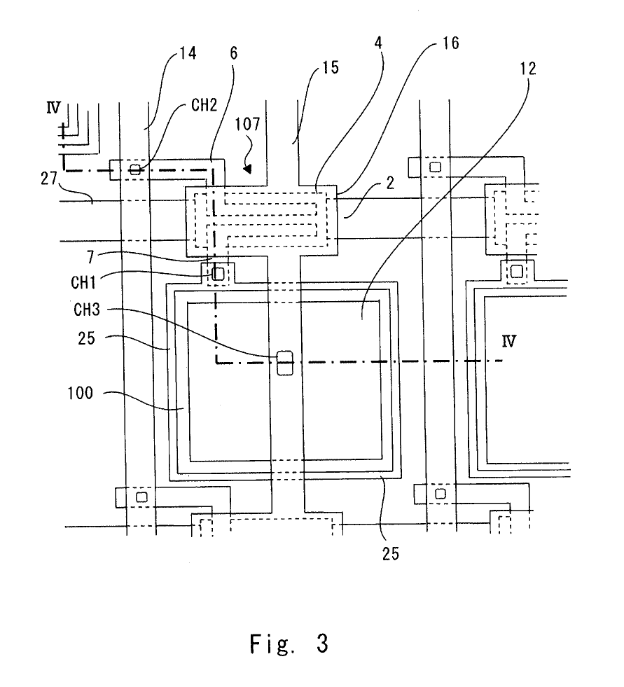

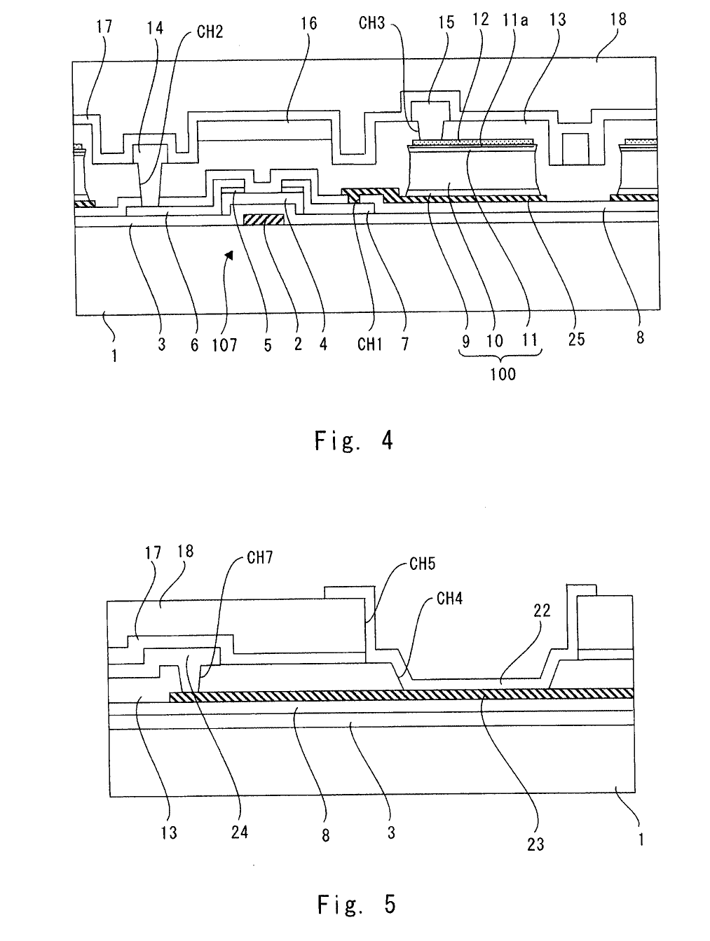

The TFT substrate is described in further detail below. Referring to FIGS. 3 and 4, the structure of the pixel 103 of the TFT substrate is described. FIG. 3 is a plan view showing the structure of the pixel 103 of the TFT substrate according to the exemplary embodiment. FIG. 3 thus shows the structure of the TFT substrate in an area surrounded by the adjacent data lines 14 and the adjacent gate lines 27. FIG. 4 is a sectional view along line IV-IV in FIG. 3.

Referring to FIG. 4, a gate electrode 2 is formed on an insulating substrate 1. The gate electrode 2 is formed integrally with the gate line 27. As the insulating substrate 1, a transparent insulating substrate such as a glass substrate may be used. The gate electrode 2 and the gate line 27 are made of a low resistance metal material. In this exemplary embodiment, the gate electrode 2 and the gate line 27 contain a metal predominantly composed of aluminum (Al). As the metal predominantly composed of Al, an Al alloy containing Ni such as AlNiNd, AlNiSi or AlNiMg, which is an Al—Ni alloy, may be used. Another Al alloy may be used as the metal predominantly composed of Al as a matter of course. Other than Al, Cu or the like may be used as the low resistance metal material.

A gate insulating layer 3 is formed to cover the gate electrode 2 and the gate line 27. On the gate insulating layer 3, a semiconductor layer 4 is formed to face the gate electrode 2. The semiconductor layer 4 is an amorphous silicon (a-Si:H) layer to which hydrogen atom is added. On the semiconductor layer 4, an ohmic contact layer 5 is formed. The ohmic contact layer 5 is a semiconductor layer that contains impurity for lower resistance. Specifically, the ohmic contact layer 5 is an n⁺a-Si:H layer which is an a-Si:H layer into which phosphorous (P) is doped as impurity.

As shown in FIG. 4, the ohmic contact layer 5 does not exist on the center part of the semiconductor layer 4. The part of the semiconductor layer 4 on which the ohmic contact layer 5 does not exist serves as a channel region. The ohmic contact layer 5 is formed on both ends of the semiconductor layer 4. One ohmic contact layer 5 serves as a source region, and the other ohmic contact layer 5 serves as a drain region. Thus, the source region and the drain region are placed in opposite sides with the channel region interposed therebetween.

A source electrode 6 and a drain electrode 7 are formed on the ohmic contact layer 5. The source electrode 6 and the drain electrode 7 are connected to the semiconductor layer 4 through the ohmic contact layer 5. The source electrode 6 is formed on the source region. The drain electrode 7 is formed on the drain region. As shown in FIG. 3, the source electrode 6 extends from the semiconductor layer 4 to the data line 14. The drain electrode 7 extends from the semiconductor layer 4 to a lower electrode 25 of the photodiode 100.

A first passivation film 8 is formed to cover the source electrode 6 and the drain electrode 7. The first passivation film 8 on the drain electrode 7 has a contact hole CH1. Thus, the first passivation film 8 does not exist partly on the drain electrode 7. The lower electrode 25 is formed substantially all over the pixel. Specifically, the lower electrode 25 is formed in the area surrounded by the adjacent gate lines 27 and the adjacent data lines 14. The lower electrode 25 is buried in the contact hole CH1. The lower electrode 25 and the drain electrode 7 are electrically connected via the contact hole CH1.

The photodiode 100 is formed substantially all over the lower electrode 25. In this exemplary embodiment, a photodiode having pin structure is used as the photodiode 100. Thus, the photodiode 100 has a structure in which an intrinsic semiconductor layer (intrinsic layer) with a small number of carriers and large resistance is placed at the middle of the pn junction. Specifically, the photodiode 100 has a three-layer structure in which an n-type semiconductor layer 9, an i-type semiconductor layer 10 and a p-type semiconductor layer 11 are sequentially laminated from the lower electrode 25 side. The n-type semiconductor layer 9 is an n-type amorphous silicon (n⁺a-Si) layer into which phosphorous (P) is doped, for example. The i-type semiconductor layer 10 is an intrinsic amorphous silicon (i-a-Si) layer, for example. The p-type semiconductor layer 11 is a p-type amorphous silicon (p⁺a-Si) layer into which boron (B) is doped, for example.

Further, a nitrogen-containing semiconductor layer 11a is formed in an upper layer of the p-type semiconductor layer 11. In other words, the nitrogen-containing semiconductor layer 11a is formed in the semiconductor layer of the photodiode 100 on the side of a transparent electrode 12. The p-type semiconductor layer 11 and the nitrogen-containing semiconductor layer 11a are formed to be substantially coincide in size when viewed from above. The nitrogen-containing semiconductor layer 11a is a p-type semiconductor layer containing nitrogen, and it serves as an anti-diffusion layer that suppresses diffusion of In or the like from the transparent electrode 12 in the upper layer to the silicon of the semiconductor layer.

Further, the transparent electrode 12 serving as a photodiode electrode is formed on the photodiode 100. Specifically, the transparent electrode 12 is formed on the nitrogen-containing semiconductor layer 11a. In other words, the nitrogen-containing semiconductor layer 11a is formed between the semiconductor layer of the photodiode 100 and the transparent electrode 12. Thus, the semiconductor layer of the photodiode 100 and the transparent electrode 12 are placed opposite to each other with the nitrogen-containing semiconductor layer 11a as an anti-diffusion layer interposed therebetween. The nitrogen-containing semiconductor layer 11a and the transparent electrode 12 are directly in contact with each other. The transparent electrode 12 is made of a transparent conductive film that is a metal oxide film. The transparent electrode 12 contains indium oxide.

The photodiode 100 is placed between the opposite electrodes. The transparent electrode 12 serves as an anode electrode of the photodiode 100. The lower electrode 25 serves as a cathode electrode of the photodiode 100. In such a structure, visible light passing through the transparent electrode 12 is input to the photodiode 100. The visible light is then converted into charge by the photodiode 100, and a current flows from the lower electrode 25.

Further, a second passivation film 13 is formed on the transparent electrode 12 to cover those layers. The second passivation film 13 may be a single transparent insulating coating, or a transparent insulating coating may be applied onto a transparent insulating film deposited by CVD or the like.

The first passivation film 8 and the second passivation film 13 above the source electrode 6 have a contact hole CH2. Thus, the first passivation film 8 and the second passivation film 13 do not exist partly on the source electrode 6. Further, the second passivation film 13 above the transparent electrode 12 has a contact hole CH3. Thus, the second passivation film 13 does not exist partly on the transparent electrode 12.

The data line 14, the bias line 15 and a light shielding layer 16 are formed on the second passivation film 13. As shown in FIG. 3, the data line 14 extends linearly across the contact hole CH2. Further, the data line 14 is buried in the contact hole CH2. The source electrode 6 and the data line 14 are electrically connected via the contact hole CH2. The data line 14 extends throughout a plurality of pixels 103 and reads charge converted by the photodiode 100 from the source electrode 6 of each pixel 103.

As shown in FIG. 3, the bias line 15 extends linearly across the contact hole CH3. Further, the bias line 15 is buried in the contact hole CH3. The transparent electrode 12 and the bias line 15 are electrically connected via the contact hole CH3. The bias line 15 extends throughout a plurality of pixels 103 and applies a reverse bias to the transparent electrode 12 of each pixel 103. The photodiode 100 is thereby turned OFF when it is not exposed to light.

The light shielding layer 16 is formed on the TFT 107. The light shielding layer 16 is in a rectangular shape. The bias line 15 and the light shielding layer 16 are formed integrally. Alternatively, the bias line 15 and the light shielding layer 16 may be formed separately. Further, the width of the light shielding layer 16 is larger than the width of the bias line 15. The data line 14 and the bias line 15 are made of a conductive film containing an Al alloy, and it is preferred to have an Al—Ni alloy film in the uppermost layer or the lowermost layer. The data line 14 and the bias line 15 may be formed by a single layer of an Al—Ni alloy film. If the Al—Ni alloy film is placed in the uppermost layer, a nitride layer may be further placed on the surface.

Further, a third passivation film 17 and a fourth passivation film 18 are sequentially formed to cover those layers. The fourth passivation film 18 has a flat surface. The fourth passivation film 18 is made of organic resin, for example. The pixel 103 of the TFT substrate has the above-described structure.

Referring then to FIG. 5, a structure of a terminal part of the TFT substrate is described. FIG. 5 is a sectional view showing a structure of a terminal part of the TFT substrate.

In the terminal part, the gate insulating layer 3 and the first passivation film 8 are sequentially formed substantially all over the insulating substrate 1. On the first passivation film 8, a wiring conversion pattern 23 is formed. The wiring conversion pattern 23 is a pattern that electrically connects a line and a terminal. Further, the wiring conversion pattern 23 may be connected to a short ring formed outside a panel. The short ring is a line placed to suppress breakdown of an element such as the TFT 107 due to static electricity or the like occurring during a manufacturing process of the TFT substrate. The second passivation film 13 is formed to cover them. The second passivation film 13 has contact holes CH4 and CH7 above the wiring conversion pattern 23. Thus, the second passivation film 13 does not exist partly on the wiring conversion pattern 23.

A line 24 is formed on the second passivation film 13. The line 24 may be extended from the data line 14 or the bias line 15. Further, the line 24 may be electrically connected to the gate line 27 via a contact hole CH6 (not shown), for example. The end of the line 24 is buried in the contact hole CH7. The line 24 and the wiring conversion pattern 23 are electrically connected via the contact hole CH7. Further, the third passivation film 17 and the fourth passivation film 18 are sequentially formed to cover the line 24. Above the contact hole CH4, the third passivation film 17 and the fourth passivation film 18 have a contact hole CH5. The contact hole CH5 is wider than the contact hole CH4. In other words, the contact hole CH4 is made inside the contact hole CH5.

On the fourth passivation film 18, a terminal 22 is formed. The terminal 22 is buried in the contact holes CH4 and CH5. The terminal 22 and the wiring conversion pattern 23 are electrically connected via the contact holes CH4 and CH5. Specifically, the wiring conversion pattern 23 is connected to the line 24 and the terminal 22, so that the line 24 and the terminal 22 are electrically connected to each other. The terminal part has the above-described structure.

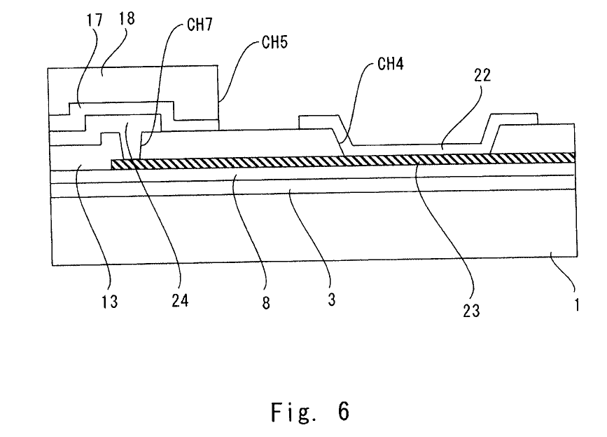

The terminal part does not necessarily have the structure described above, and it may have the structure shown in FIG. 6, for example. FIG. 6 is a sectional view showing another structure of the terminal part. In this structure, the terminal 22 is not formed on the fourth passivation film 18 and formed on the third passivation film 17 as shown in FIG. 6. Thus, the terminal 22 is formed only inside the contact hole CH5.

Although the wiring conversion pattern 23 is placed on top of the first passivation film 8 in this exemplary embodiment, the wiring conversion pattern 23 may be placed between the gate insulating layer 3 and the first passivation film 8. Further, although the data line 14, the bias line 15 and the gate line 27 are electrically connected to the wiring conversion pattern 23 via the contact hole CH7 or the like in FIGS. 5 and 6, the structure is not limited thereto. For example, the line 24 such as the data line 14, the bias line 15 and the gate line 27 may be directly used as the wiring conversion pattern 23 without via the contact hole CH7 or the like. In other words, the data line 14, the bias line 15 and the gate line 27 may be directly connected to the terminal 22.

The TFT substrate included in the photosensor according to the exemplary embodiment has the above-described structure. In this structure, the nitrogen-containing semiconductor layer 11a serving as an anti-diffusion layer is formed in the p-type semiconductor layer 11 on the transparent electrode 12 side. This enables suppression of In diffusion from the anode electrode of the photodiode 100 to the Si layer. Thus, the structure enables suppression of In diffusion from the transparent electrode 12 to the semiconductor layer composed of the n-type semiconductor layer 9, the i-type semiconductor layer 10 and the p-type semiconductor layer 11. It is thereby possible to suppress a leakage current of the photodiode 100 under a high bias voltage, thereby achieving a photosensor with less afterimages.

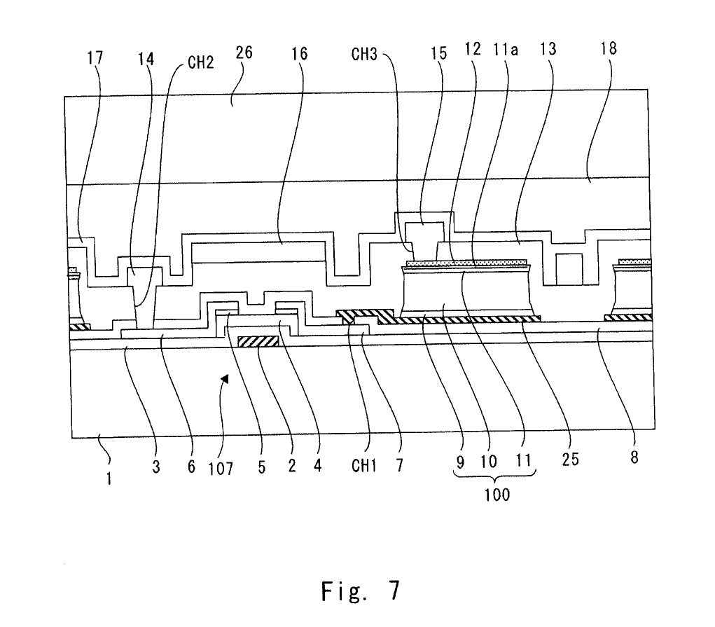

As described earlier, a scintillator is included in the photosensor used in the X-ray imaging device. Specifically, a scintillator is mounted on the TFT substrate that is included in the photosensor. FIG. 7 is a sectional view showing a structure of the TFT substrate used in the X-ray imaging device. As shown in FIG. 7, a scintillator 26 is formed on the fourth passivation film 18. The scintillator 26 is placed on the light incident side of the photodiode 100. Thus, the scintillator 26 is placed on the transparent electrode 12 side of the photodiode 100. The scintillator 26 is made of CsI, for example, and converts X rays into visible light. The structure different from the scintillator 26 is substantially the same as that of the TFT substrate shown in FIG. 4.

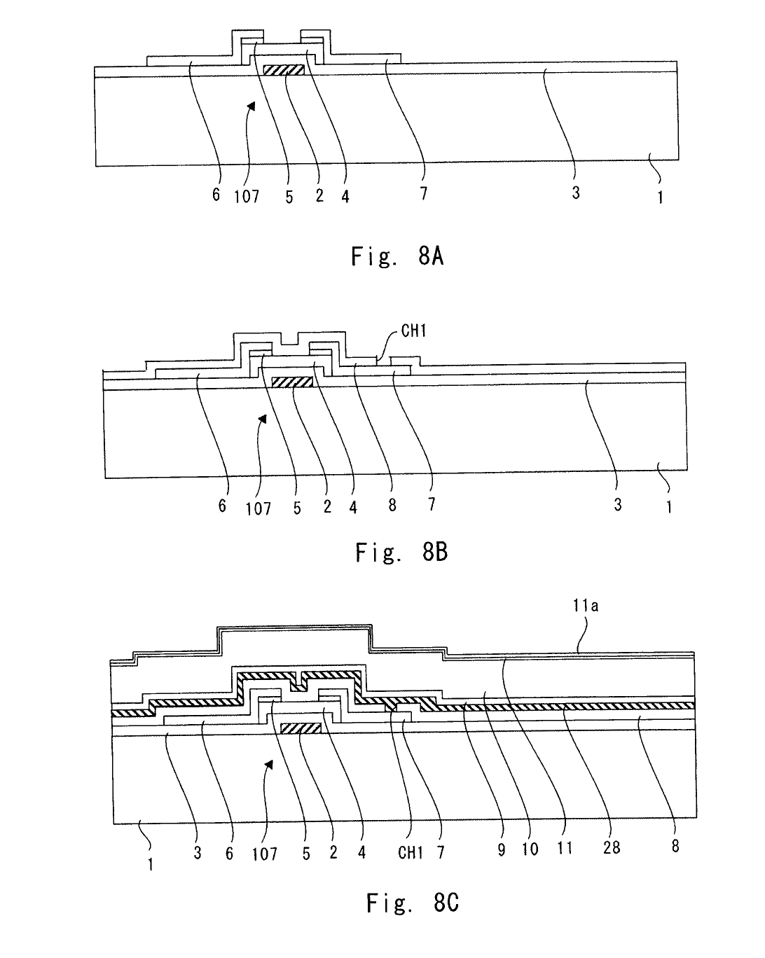

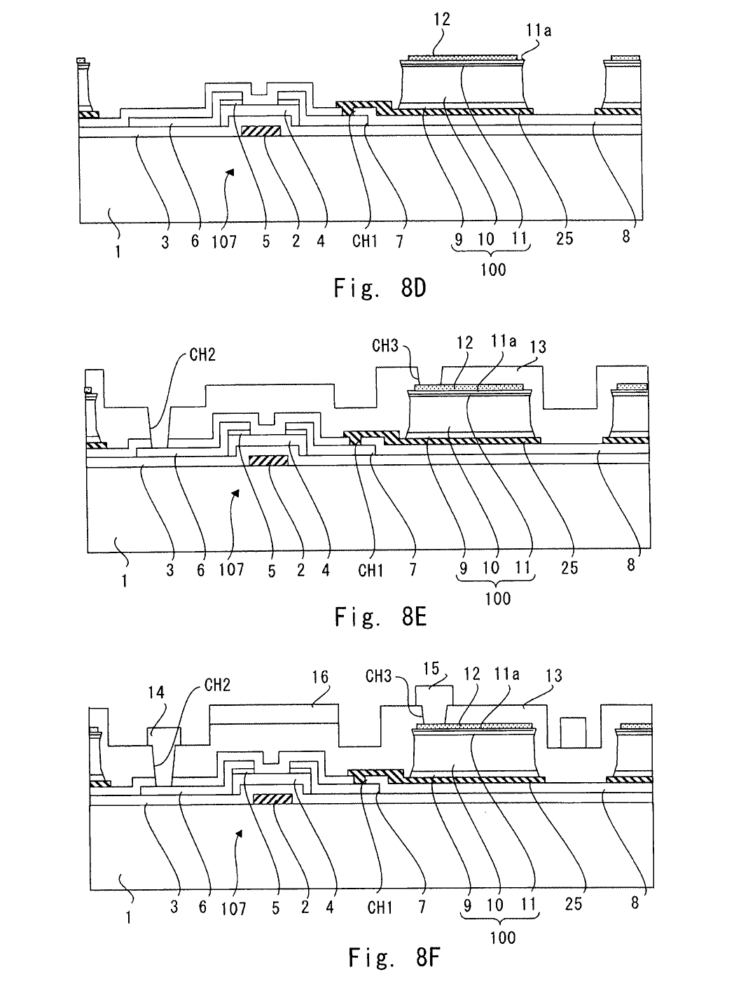

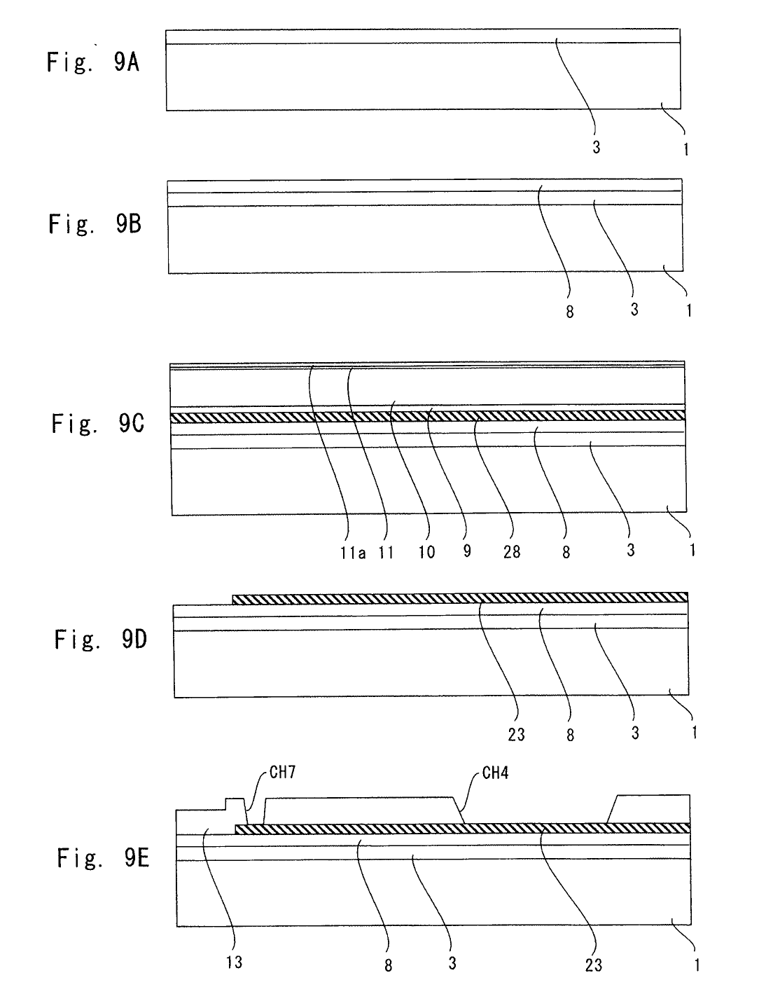

A method of manufacturing the TFT substrate included in the photosensor according to the exemplary embodiment is described hereinafter with reference to FIGS. 8A to 8F and FIGS. 9A to 9E. FIGS. 8A to 8F are sectional views showing a manufacturing process of a TFT substrate in a pixel. Specifically, FIGS. 8A to 8F are sectional views showing a manufacturing process of a TFT substrate in the part corresponding to FIG. 4. FIGS. 9A to 9E are sectional views showing a manufacturing process of a TFT substrate in a terminal part. Thus, FIGS. 9A to 9E are sectional views showing a manufacturing process of a TFT substrate in the part corresponding to FIG. 5 or 6.

First, a first conductive thin film is deposited on the insulating substrate 1 by sputtering. It is preferred to use a low resistance metal material as a material of the first conductive thin film. Specifically, as a material of the first conductive thin film, a metal predominantly composed of Al, e.g. an Al alloy containing Ni, may be used. In this exemplary embodiment, AlNiNd is used as a material of the first conductive thin film. Deposition conditions are a pressure of 0.2 to 0.5 Pa, a DC power of 1.0 to 2.5 kW (or a power density of 0.17 to 0.43 W/cm²), and a deposition temperature in the range of a room temperature to 180° C., for example. A film thickness is 150 to 300 nm.

In order to suppress reaction with a developer, a nitride AlNiNd layer (an AlNiNdN layer) may be formed on AlNiNd. Further, AlNiSi, AlNiMg or the like may be used instead of AlNiNd. Furthermore, the same material may be used for the data line 14 and the bias line 15, which improves production efficiency. As a low resistance metal material, Cu or an Cu alloy, rather than Al, may be used. In this case also, the film may be deposited by sputtering just like the case of using Al.

In this exemplary embodiment, the gate electrode 2 and the gate line 27 are not exposed when forming the photodiode 100. Therefore, a metal predominantly composed of Al or Cu, which is not highly resistant to damage, can be used as the gate electrode 2 and the gate line 27. A low resistance line can be thereby formed, which enables fabrication of a large-size photosensor.

Next, resist (not shown), which is photosensitive resin, is applied onto the first conductive thin film by spin coating, and the first photolithography process for exposure and development of the applied resist is performed. The resist is thereby patterned into a desired shape. After that, the first conductive thin film is etched by using the resist as a mask and patterned into a desired shape. The resist is then removed. The gate electrode 2 and the gate line 27 are thereby formed.

Etching is performed by wet etching using an etchant that is mixed acid of phosphoric acid, nitric acid and acetic acid, for example. An etchant is not limited to mixed acid of phosphoric acid, nitric acid and acetic acid, and another etchant may be used. Further, etching is not limited to wet etching, and dry etching may be used. The cross sectional shape of the gate electrode 2 and the gate line 27 is preferably a tapered shape. By forming a tapered shape, it is possible to reduce the occurrence of break or the like in the subsequent film formation process. This has an effect of improving the withstand voltage of the insulating layer.

Then, the gate insulating layer 3, the semiconductor layer 4 and the ohmic contact layer 5 are sequentially deposited by plasma CVD so as to cover the gate electrode 2 and the gate line 27. An a-Si:H layer may be used as the semiconductor layer 4, and an n⁺a-Si:H layer may be used as the ohmic contact layer 5. The gate insulating layer 3 is deposited with a thickness of 200 to 400 nm, the semiconductor layer 4 is deposited with a thickness of 100 to 200 nm, and the ohmic contact layer 5 is deposited with a thickness of 20 to 50 nm, for example.

It should be noted that, because high charge reading efficiency is required and a TFT with high driving capacity is demanded for the photosensor, the semiconductor layer 4 may be deposited in two separate steps in order to enhance the performance of the TFT. As the deposition conditions in this case, a first layer is deposited with a low deposition rate of 5 to 20 nm/min to thereby form a high quality film, and the other layer is deposited with a deposition rate of 30 nm/min or higher. Further, the gate insulating layer 3, the semiconductor layer 4 and the ohmic contact layer 5 are deposited with a deposition temperature of 250 to 350° C.

Then, island-shaped resist (not shown) is formed on the gate electrode 2 by the second photolithography process. The semiconductor layer 4 and the ohmic contact layer 5 are then etched by using the resist as a mask. Etching is performed by dry etching using plasma with mixed gas of SF₆ and HCl, for example. Etching gas is not limited to mixed gas of SF₆ and HCl, and another etching gas may be used. After that, the resist is removed. The semiconductor layer 4 and the ohmic contact layer 5 are thereby patterned into an island shape. In this step, the ohmic contact layer 5 remains also on a channel region, which is formed later.

Further, resist (not shown) for making an opening only on the periphery of the substrate is formed on the gate insulating layer 3 by the third photolithography process. Then, the gate insulating layer 3 is etched by using the resist as a mask. Etching is performed by dry etching using plasma with mixed gas of CF₄ and O₂, for example. Etching gas is not limited to mixed gas of CF₄ and O₂, and another etching gas may be used.

After that, a second conductive thin film is deposited by sputtering so as to cover the ohmic contact layer 5. As the second conductive thin film, a high melting point metal film such as Cr may be used. The thickness of the second conductive thin film is 50 to 300 nm. A material of the second conductive thin film may be a metal that can form ohmic contact with Si, instead of Cr.

Then, resist (not shown) corresponding to the source electrode 6 and the drain electrode 7 is formed on the second conductive thin film by the fourth photolithography process. Using the resist as a mask, the second conductive thin film is etched to form the source electrode 6 and the drain electrode 7. Etching is performed by wet etching using mixed acid of ceric ammonium nitrate and nitric acid, for example. After that, the ohmic contact layer 5 is etched by using the formed electrode as a mask. A channel is thereby formed, and the TFT 107 is formed. Etching in this step is performed by dry etching using plasma with mixed gas of SF₆ and HCl, for example.

An etchant is not limited to mixed acid of ceric ammonium nitrate and nitric acid, and another etchant may be used. Further, etching gas is not limited to mixed gas of SF₆ and HCl, and another etching gas may be used.

Note that, in the terminal part, the first conductive thin film, the semiconductor layer 4, the ohmic contact layer 5 and the second conductive thin film are removed by the first, second and fourth photolithography processes and etching. Further, the gate insulating layer 3 is formed substantially all over the insulating substrate 1. By the above process, the structure shown in FIG. 8A and FIG. 9A is produced.

After that, in order to improve the properties of the TFT 107, plasma processing using hydrogen gas may be further performed before forming the first passivation film 8 to thereby rough the back channel, which is the surface of the semiconductor layer 4.

Then, the first passivation film 8 is deposited by plasma CVD or the like so as to cover those layers. In this exemplary embodiment, a silicon oxide (SiO₂) film with a low permittivity is used as the first passivation film 8. The SiO₂ film is formed with a thickness of 200 to 400 nm. Deposition conditions of the SiO₂ film are a SiH₄ flow of 1.69×10⁻² to 8.45×10⁻² Pa·m³/s (10 to 50 sccm), an N₂O flow of 3.38×10⁻¹ to 8.45×10⁻¹ Pa·m³/s (200 to 500 sccm), a deposition pressure of 50 Pa, an RF power of 50 to 200 W (or a power density of 0.015 to 0.67 W/cm²), and a deposition temperature of 200 to 300° C., for example. The first passivation film 8 is not limited to the SiO₂ film, and SiN, SiON, or a laminated layer of those films may be used. In this case, the film is deposited by adding hydrogen, nitrogen or NH₃ to the above gas.

Then, resist (not shown) for making the contact hole CH1 is formed by the fifth photolithography process. Using the resist as a mask, the first passivation film 8 is etched. Etching is performed by dry etching using plasma with mixed gas of CF₄ and O₂, for example. Further, etching gas is not limited to mixed gas of CF₄ and O₂, and another etching gas may be used. The resist is then removed. The contact hole CH1 is thereby made. Specifically, the first passivation film 8 above the drain electrode 7 is removed to make the contact hole CH1. Thus, the drain electrode 7 is exposed at the contact hole CH1. In the terminal part, the first passivation film 8 is formed substantially all over the gate insulating layer 3. By the above process, the structure shown in FIG. 8B and FIG. 9B is produced.

After that, a third conductive thin film 28 to serve as the lower electrode 25 is deposited on the first passivation film 8 by sputtering or the like. The third conductive thin film 28 is buried in the contact hole CH1. As the third conductive thin film 28, a high melting point metal film such as Cr may be used.

Subsequently, the n-type semiconductor layer 9, the i-type semiconductor layer 10 and the p-type semiconductor layer 11 are sequentially deposited on the third conductive thin film 28 by plasma CVD. Those layers constitute the photodiode 100. Those layers are deposited in a sequential order in the same deposition chamber without breaking a vacuum. In this exemplary embodiment, a P-doped n⁺a-Si layer is deposited as the n-type semiconductor layer 9, an i-a-Si layer is deposited as the i-type semiconductor layer 10, and a B-doped p⁺a-Si layer is deposited as the p-type semiconductor layer 11. The n⁺a-Si layer is deposited with a thickness of 5 to 100 nm, the i-a-Si layer is deposited with a thickness of 0.5 to 2.0 μm, and the p⁺a-Si layer is deposited with a thickness of 10 to 80 nm.

Deposition conditions of the i-a-Si layer are an SiH₄ flow of 1.69×10⁻¹ to 3.38×10−1 Pa·m³/s (100 to 200 sccm), an H₂ flow of 1.69×10⁻¹ to 5.07×10⁻¹ Pa·m³/s (100 to 300 sccm), a deposition pressure of 100 to 300 Pa, an RF power of 30 to 150 W (or a power density of 0.01 to 0.05 W/cm²), and a deposition temperature of 200 to 300° C., for example. The P-doped n⁺a-Si layer and the B-doped p⁺a-Si layer are deposited with use of deposition gas in which PH₃ or B₂H₆ at 0.2% to 1.0% is mixed with gas under the above deposition conditions.

Further, the p⁺a-Si layer may be formed by introducing B into an upper layer part of the i-type semiconductor layer 10 by ion shower doping or ion implantation. In the case of forming the p⁺a-Si layer by ion implantation, a SiO₂ film with a thickness of 5 to 40 nm may be formed on the surface of the i-a-Si layer before forming the p⁺a-Si layer. This reduces damage when implanting B. In this case, the SiO₂ film may be removed by BHF or the like after ion implantation.

After depositing the p-type semiconductor layer 11, the nitrogen-containing semiconductor layer 11a is deposited. The nitrogen-containing semiconductor layer 11a is formed with a thickness of 1 to 5 nm. The nitrogen-containing semiconductor layer 11a is deposited by adding NH₄ of 1.69×10⁻² to 1.67×10⁻¹ Pa·m³/s (several tens of sccm) to the deposition gas of the p⁺a-Si layer. In other words, at the late stage of deposition of the p-type semiconductor layer 11, deposition is performed by adding gas containing nitrogen to thereby form the nitrogen-containing semiconductor layer 11a in the upper layer of the p-type semiconductor layer 11. The deposited nitrogen-containing semiconductor layer 11a contains a larger content of silicon compared to a composition ratio of quantum silicon nitride. The p-type semiconductor layer 11 having the nitrogen-containing semiconductor layer 11a in the upper layer is thereby formed.

Although the case where the nitrogen-containing semiconductor layer 11a is formed by a deposition method is described above, it is not limited thereto. For example, after depositing the p-type semiconductor layer 11, surface treatment of the deposited p-type semiconductor layer 11 is performed in an atmosphere containing nitrogen plasma. The silicon on the surface of the p-type semiconductor layer 11 is thereby transformed into nitrogen-containing silicon, so that the nitrogen-containing semiconductor layer 11a can be formed in the upper layer of the p-type semiconductor layer 11. Further, in this case, it is preferred to perform deposition of the n-type semiconductor layer 9, the i-type semiconductor layer 10 and the p-type semiconductor layer 11 and formation of the nitrogen-containing semiconductor layer 11a in one device. Specifically, it is preferred to form the nitrogen-containing semiconductor layer 11a by creating an atmosphere containing nitrogen plasma in a silicon deposition device for depositing those semiconductor layers. This enables simplification of the manufacturing process.

Furthermore, after deposition processing of three-layer silicon, surface treatment may be performed by a device such as atmospheric pressure plasma. Specifically, after sequentially depositing the n-type semiconductor layer 9, the i-type semiconductor layer 10 and the p-type semiconductor layer 11, surface treatment may be performed to form the nitrogen-containing semiconductor layer 11a on the surface of the p-type semiconductor layer 11. By the above process, the third conductive thin film 28, the n-type semiconductor layer 9, the i-type semiconductor layer 10, the p-type semiconductor layer 11 and the nitrogen-containing semiconductor layer 11a are sequentially formed on the first passivation film 8, so that the structure shown in FIG. 8C and FIG. 9C is produced.

Then, a fourth conductive thin film is deposited on the nitrogen-containing semiconductor layer 11a. Formation of the fourth conductive thin film is performed by depositing a transparent conductive film such as ITO by using sputtering, for example. The thickness of the fourth conductive thin film is 50 to 300 nm, for example. This deposition is preferably performed under conditions without heating the substrate. After depositing the fourth conductive thin film, resist (not shown) that is smaller than a pattern of the photodiode 100 by the size of a processing margin is formed by the sixth photolithography process. The fourth conductive thin film is then etched by using the resist as a mask. After that, the resist is removed. The transparent electrode 12 is thereby formed.

Then, resist (not shown) in a photosensitive area of the photodiode 100 is formed on the transparent electrode 12 by the seventh photolithography process. Using the resist as a mask, an a-Si layer is etched. Specifically, three layers of the n-type semiconductor layer 9, the i-type semiconductor layer 10 and the p-type semiconductor layer 11 are etched. Etching is performed by dry etching using plasma with mixed gas of SF₆ and HCl, for example. Etching gas is not limited to mixed gas of SF₆ and HCl, and another etching gas may be used. After that, the resist is removed. The photodiode 100 having a three-layer structure is thereby formed.

Then, resist (not shown) corresponding to the lower electrode 25 is formed by the eighth photolithography process. The resist has a pattern that is slightly larger than the pattern of the photodiode 100. Using the resist as a mask, the third conductive thin film 28 is etched. After that, the resist is removed. The lower electrode 25 is thereby formed. Further, the lower electrode 25 is formed also in the contact hole CH1, so that the lower electrode 25 and the drain electrode 7 are electrically connected via the contact hole CH1.

In the terminal part, the fourth conductive thin film and the a-Si layer are removed by the sixth and seventh photolithography processes and the etching process. Then, the third conductive thin film 28 is patterned by the eighth photolithography process and the etching process. The wiring conversion pattern 23 is thereby formed. Although the wiring conversion pattern 23 is formed by using the third conductive thin film 28 in this example, it is not limited thereto. For example, the wiring conversion pattern 23 may be formed by depositing and patterning another conductive thin film, or the second conductive thin film may be used for the wiring conversion pattern 23. By the above process, the structure shown in FIG. 8D and FIG. 9D is produced.

Then, the second passivation film 13 for protecting the photodiode 100 is deposited on the transparent electrode 12. The second passivation film 13 is formed in order to reduce a load capacity on the data line 14 and the bias line 15. Thus, a silicon oxide (SiO₂) film with a low permittivity with a thickness of 0.5 to 1.5 μM, for example, is used as the second passivation film 13.

Deposition conditions of the SiO₂ film are a SiH₄ flow of 1.69×10⁻² to 8.45×10⁻² Pa·m³/s (10 to 50 sccm), an N₂O flow of 3.38×10⁻¹ to 8.45×10⁻¹ Pa·m³/s (200 to 500 sccm), a deposition pressure of 50 Pa, an RF power of 50 to 200 W (or a power density of 0.015 to 0.67 W/cm²), and a deposition temperature of 200 to 300° C., for example. Although the SiO₂ film is taken as an example of the second passivation film 13, it is not limited thereto. The second passivation film 13 may be a laminated film such as SiO₂/SiN/SiO₂, or a single film of spin coating on glass (SOG) or a laminated film of a CVD formation film and an SOG film for step reduction.

Then, resist (not shown) for making the contact holes CH2 and CH3 is formed by the ninth photolithography process. The second passivation film 13 and the first passivation film 8 are then etched by using the resist as a mask. Etching is performed by dry etching using plasma with mixed gas of CF₄ and Ar, for example. Etching gas is not limited to mixed gas of CF₄ and Ar, and another etching gas may be used. After that, the resist is removed. The contact holes CH2 and CH3 are thereby made.

Specifically, the first passivation film 8 and the second passivation film 13 above the source electrode 6 are removed, so that the contact hole CH2 is made. Thus, the source electrode 6 is exposed at the contact hole CH2. Then, the second passivation film 13 above the transparent electrode 12 is removed, so that the contact hole CH3 is made. Thus, the transparent electrode 12 is exposed at the contact hole CH3. In the terminal part, the second passivation film 13 above the wiring conversion pattern 23 is removed, so that the contact holes CH4 and CH7 are made. Thus, the wiring conversion pattern 23 is exposed at the contact holes CH4 and CH7. Although the contact hole CH4 is made at the same time as making the contact hole CH7 in this exemplary embodiment, it may be made in a different step. Further, if the contact holes CH2, CH3, CH4, CH6 and CH7 are formed to have a tapered cross section, the coating property of a layer placed thereabove is improved, which reduces the occurrence of break or the like. By the above process, the structure shown in FIG. 8E and FIG. 9E is produced.

Then, on the second passivation film 13, a fifth conductive thin film to serve as the data line 14, the bias line 15 and the light shielding layer 16 is deposited. The fifth conductive thin film is buried in the contact holes CH2 and CH3. As the fifth conductive thin film, an Al alloy containing Ni or the like having a low resistance, a high heat resistance and suitable contact properties with a transparent conductive film is used. For example, an AlNiNd film is used as the fifth conductive thin film. The AlNiNd film is deposited with a thickness of 0.5 to 1.5 μm. The fifth conductive thin film may be a single layer of AlNiNd, or a laminated layer of AlNiNd and Mo or Mo alloy, or a high melting point metal such as Cr. Further, in order to suppress reaction with a developer, a nitride AlNiNd layer (an AlNiNdN layer) may be formed on AlNiNd.

For example, an Mo alloy is deposited as a base and AlNiNd is deposited thereon in succession by sputtering or the like. Deposition conditions are a pressure of 0.2 to 0.5 Pa, a DC power of 1.0 to 2.5 kW (or a power density of 0.17 to 0.43 W/cm²), and a deposition temperature in the range of a room temperature to 180° C., for example.

Then, resist (not shown) corresponding to the data line 14, the bias line 15 and the light shielding layer 16 is formed by the tenth photolithography process. The fifth conductive thin film is then etched by using the resist as a mask. In the case of using a laminated film of AlNiNd and Mo as the fifth conductive thin film, etching is performed by wet etching using mixed acid of phosphoric acid, nitric acid and acetic acid, for example. An etchant is not limited to mixed acid of phosphoric acid, nitric acid and acetic acid, and another etchant may be used. After that, the resist is removed. The data line 14, the bias line 15 and the light shielding layer 16 are thereby formed.

Further, the data line 14 is formed in the contact hole CH2, and the data line 14 and the source electrode 6 are connected via the contact hole CH2. The bias line 15 is formed in the contact hole CH3, and the bias line 15 and the transparent electrode 12 are connected via the contact hole CH3. In the terminal part, the fifth conductive thin film is removed. By the above process, the structure shown in FIG. 8F is produced.

After that, the third passivation film 17 and the fourth passivation film 18 are sequentially deposited to cover the data line 14 and the bias line 15 so as to protect them. For example, a SiN layer is used as the third passivation film 17, and a planarized film is used as the fourth passivation film 18.

Then, resist (not shown) for making the contact hole CH5 is formed by the eleventh photolithography process. Then, the third passivation film 17 and the fourth passivation film 18 are etched by using the resist as a mask. After that, the resist is removed. The third passivation film 17 and the fourth passivation film 18 above the wiring conversion pattern 23 are thereby removed, so that the contact hole CH5 is made. At the contact hole CH5, the second passivation film 13 and the wiring conversion pattern 23 are exposed. Further, at the contact hole CH4 inside the contact hole CH5, the wiring conversion pattern 23 is exposed.

Etching in this step is used by dry etching using plasma with mixed gas of CF₄ and O₂. Etching gas is not limited to mixed gas of CF₄ and O₂, and another etching gas may be used. A photosensitive planarized film may be used as the fourth passivation film 18. The fourth passivation film 18 can be thereby patterned by exposure and development processing without using resist in the eleventh photolithography process.

Then, a sixth conductive thin film to serve as the terminal 22 is deposited on the fourth passivation film 18. The sixth conductive thin film is buried in the contact holes CH4 and CH5. As the sixth conductive thin film, a transparent conductive film such as amorphous ITO, for example, is used to ensure reliability. Although a transparent conductive film is used as the terminal 22 in this exemplary embodiment, a two-layer structure of a conductive film and a transparent conductive film may be used in order to establish favorable contact with the wiring conversion pattern 23 or the like.

Then, resist (not shown) in a terminal shape is formed by the twelfth photolithography process. The sixth conductive thin film is then etched by using the resist as a mask. Etching is performed by wet etching using oxalic acid, for example. After that, the resist is removed. The terminal 22 is thereby formed. Further, the terminal 22 is formed in the contact holes CH4 and CH5, and the wiring conversion pattern 23 and the terminal 22 are electrically connected via the contact holes CH4 and CH5. After that, ITO is crystallized by annealing. By the above process, the structure shown in FIG. 4 and FIG. 5 or 6 is produced, so that the TFT substrate is completed.

In the method of manufacturing the TFT substrate that is included in the photosensor according to the exemplary embodiment, the nitrogen-containing semiconductor layer 11a is formed in the upper layer of the p-type semiconductor layer 11. This suppresses diffusion of In or the like of a transparent conductive film constituting the transparent electrode 12 to a semiconductor layer constituting the photodiode 100. It is thereby possible to suppress reduction of quantum efficiency of the photodiode 100 and achieve a large-size photosensor with a good S/N ratio even at low incident light intensity.

Further, although the nitrogen-containing semiconductor layer 11a is formed as an anti-diffusion layer in this exemplary embodiment, a layer containing oxygen may be formed instead. Specifically, oxygen may be contained in the p-type semiconductor layer 11 on the transparent electrode 12 side. In this case, an anti-diffusion layer is formed by performing surface treatment of the deposited p-type semiconductor layer 11 in an atmosphere containing oxygen plasma, for example. Deposition of the semiconductor layers and formation of the anti-diffusion layer may be performed in one device, as in the case of the nitrogen-containing semiconductor layer 11a.

Although the TFT substrate is manufactured by twelve times of photolithography processes in the exemplary embodiment, the TFT substrate may be manufactured by eleven times of photolithography processes. Specifically, the number of times of performing photolithography process can be reduced by performing the second photolithography process and the fourth photolithography process in one process. Thus, patterning of the semiconductor layer 4 and the ohmic contact layer 5 into an island shape and formation of the source electrode 6, the drain electrode 7 and the ohmic contact layer 5 can be performed in one-time photolithography process.

In this case, after depositing the ohmic contact layer 5, the second conductive thin film is deposited thereon. Then, resist having two levels of film thickness is formed on the second conductive thin film. Specifically, a thick resist pattern is formed on the source electrode 6 and the drain electrode 7, which are formed later. Then, a thin resist pattern is formed on a channel region, which is formed later. Resist is not formed on the other regions. Then, the semiconductor layer 4, the ohmic contact layer 5 and the second conductive thin film are etched by using the resist as a mask. After that, the thin resist pattern is removed, and the ohmic contact layer 5 is etching by using the thick resist pattern as a mask. After that, the thick resist pattern is removed. The source electrode 6, the drain electrode 7 and the channel region are thereby formed.

In the formation of resist having two levels of film thickness, a multi-tone mask that enables three exposure levels for an exposed area, an intermediate exposed area and an unexposed area may be used. The multi-tone mask involves a half-tone mask and a gray-tone mask. By using such a multi-tone mask, resist having two levels of film thickness as described above can be formed in one-time exposure.

Further, although the gate insulating film 3 on the periphery of the substrate is removed by using the resist pattern formed by the third photolithography process in the exemplary embodiment, the present invention is not limited thereto. For example, the gate insulating film 3 on the periphery may be removed after forming the source electrode 6 and the drain electrode 7. Alternatively, the ohmic contact layer 5, the semiconductor layer 4 and the gate insulating film 3 on the periphery of the substrate may be removed at the same time after depositing the ohmic contact layer 5. Further, the first passivation film 8 and the gate insulating film 3 may be removed in the process of making the contact hole CH1. It is preferred to use etching conditions that minimize dry etching damage on the drain electrode 7.

Further, although the third conductive thin film 28 is deposited as the lower electrode 25 on the contact hole CH1, and the photodiode 100 is formed thereon in the exemplary embodiment, the present invention is not limited thereto. For example, the drain electrode 7 may be used also as the lower electrode 25, and the photodiode 100 may be formed in the contact hole CH1 above the drain electrode 7. Further, the third conductive thin film 28 may be formed as the lower electrode 25 on the contact hole CH1 above the drain electrode 7, and the photodiode 100 may be formed in the contact hole CH1.

### Second Exemplary Embodiment

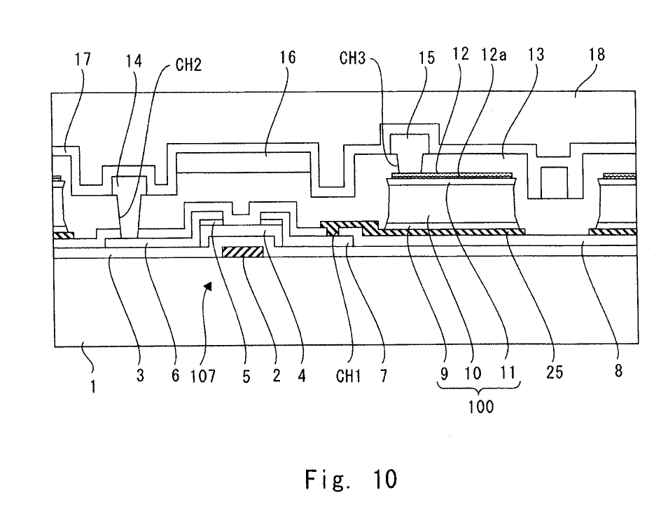

Another exemplary embodiment of the present invention is described hereinafter with reference to the drawings. In this exemplary embodiment, a high concentration oxygen-containing conductive layer 12a is provided in place of the nitrogen-containing semiconductor layer 11a as an anti-diffusion layer. The other structure, manufacturing method or the like is the same as those of the first exemplary embodiment, and description is thus omitted or simplified as appropriate. FIG. 10 is a sectional view showing a structure of a TFT substrate included in a photosensor according to the exemplary embodiment. FIG. 10 is a sectional view along line IV-IV in FIG. 3. Thus, FIG. 10 is a sectional view in the same part as FIG. 4.

The structure of the layers below the lower electrode 25 of the photodiode 100 is the same as that of the first exemplary embodiment, and description thereof is omitted. In the upper layer of the lower electrode 25, the photodiode 100 having a three-layer structure in which the n-type semiconductor layer 9, the i-type semiconductor layer 10 and the p-type semiconductor layer 11 are sequentially laminated is formed. Further, the transparent electrode 12 is formed on the photodiode 100.

The transparent electrode 12 has the high concentration oxygen-containing conductive layer 12a as an anti-diffusion layer at the interface with the p-type semiconductor layer 11. Thus, the high concentration oxygen-containing conductive layer 12a is formed in the transparent electrode 12 on the p-type semiconductor layer 11 side. The high concentration oxygen-containing conductive layer 12a is a layer that contains a larger content of oxygen compared to the middle part of the transparent electrode 12 in the thickness direction. In other words, the high concentration oxygen-containing conductive layer 12a has a higher composition ratio of oxygen than a composition ratio of oxygen at the middle part of the transparent electrode 12 in the film thickness direction. The structure of the layers above the second passivation film 13 is the same as that of the first exemplary embodiment, and description thereof is omitted.

In the TFT substrate included in the photosensor according to the exemplary embodiment, the transparent electrode 12 has the high concentration oxygen-containing conductive layer 12a at the interface with the p-type semiconductor layer 11. This suppresses diffusion of In or the like to the p-type semiconductor layer 11. It is thereby possible to suppress reduction of quantum efficiency of the photodiode 100 and achieve a large-size photosensor with a good S/N ratio even at low incident light intensity.

Although the high concentration oxygen-containing conductive layer 12a that contains a large content of oxygen is used as an example of an anti-diffusion layer in the exemplary embodiment, a layer that contains a large content of nitrogen may be formed instead. Thus, a layer that contains nitrogen may be formed in the transparent electrode 12 on the p-type semiconductor layer 11 side. Furthermore, a layer that contains a large content of zinc may be used as an anti-diffusion layer. Specifically, a layer that has a higher composition ratio of zinc than a composition ratio of zinc at the middle part of the transparent electrode 12 in the film thickness direction may be formed in the transparent electrode 12 on the p-type semiconductor layer 11 side.

A method of manufacturing the TFT substrate included in the photosensor according to the exemplary embodiment is described hereinafter.

The process up to the deposition of the n-type semiconductor layer 9, the i-type semiconductor layer 10 and the p-type semiconductor layer 11 constituting the photodiode 100 is the same as described in the first exemplary embodiment. On the p-type semiconductor layer 11, a transparent conductive film is deposited as a fourth conductive thin film. As the transparent conductive film, an amorphous transparent conductive film is deposited. The amorphous transparent conductive film is deposited by sputtering with use of a target such as IZO, ITZO, ITO or ITSO, for example. Deposition conditions are a pressure of 0.3 to 0.6 Pa, a DC power of 3 to 10 kW (or a power density of 0.65 to 2.3 W/cm²), an Ar flow of 8.45×10⁻² to 2.535×10⁻¹ Pa·m³/s (50 to 150 sccm), an oxygen flow of 1.69×10⁻³ to 3.38×10⁻³ Pa·m³/s (1 to 2 sccm), and a deposition temperature in the range of a room temperature to 180° C., for example.

During deposition of the amorphous transparent conductive film, an oxygen flow changes. Specifically, an oxygen flow at the initial stage of deposition is set to be higher than an oxygen flow at the intermediate stage of deposition of the amorphous transparent conductive film. For example, a higher oxygen flow is set until the film thickness reaches about 5 nm to 10 nm. The high concentration oxygen-containing conductive layer 12a is deposited in the lower layer of the amorphous transparent conductive film by increasing an oxygen content in this manner. A change in oxygen flow may be a step-like change or a ramp-like change. Further, a change in oxygen content is not necessarily caused by an oxygen flow.

Then, resist (not shown) is formed by the sixth photolithography process, etched by using oxalic acid, for example, and patterned. The transparent electrode 12 having the high concentration oxygen-containing conductive layer 12a is thereby formed. The subsequent manufacturing process is the same as that of the first exemplary embodiment and thus not redundantly described.

Although an oxygen flow or the like is changed in order to increase an oxygen content of the transparent electrode 12 on the p-type semiconductor layer 11 side in this exemplary embodiment, N₂ may be added in addition to O₂ at the initial stage of deposition so as to contain nitrogen. Thus, the transparent conductive film to serve as the transparent electrode 12 may be deposited by adding gas containing nitrogen at the initial stage of deposition. Further, when forming a layer that contains a large content of zinc, an anti-diffusion layer may be formed in the lower layer of the transparent conductive film to serve as the transparent electrode 12 by depositing a material containing a larger content of zinc at the initial stage of deposition than at the intermediate stage of deposition. Specifically, in order to increase a zinc content in the layer deposited at the initial stage, the film is deposited with a thickness of 5 nm to 10 nm with use of a target containing a large content of zinc such as IZO or ITZO. After that, a laminated film may be formed by depositing with use of another target such as ITO. Further, the film may be formed by preparing two kinds of targets in one deposition chamber.

### Third Exemplary Embodiment

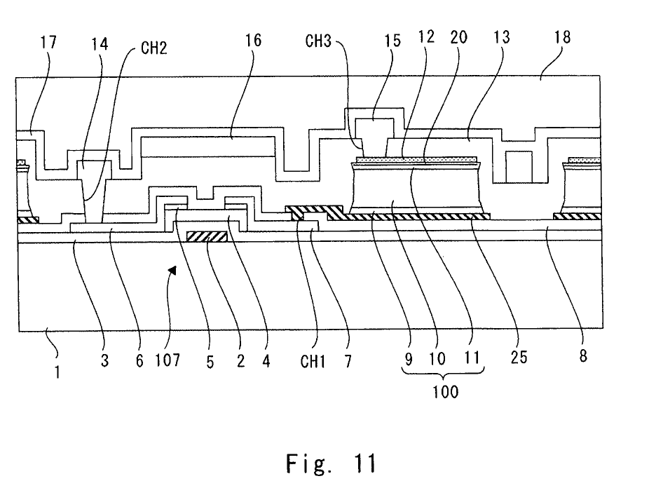

Another exemplary embodiment of the present invention is described hereinafter with reference to the drawings. In this exemplary embodiment, a silicide layer 20 is provided as an anti-diffusion layer in place of the nitrogen-containing semiconductor layer 11a. The other structure, manufacturing method or the like is the same as those of the first exemplary embodiment, and description is thus omitted or simplified as appropriate. FIG. 11 is a sectional view showing a structure of a TFT substrate included in a photosensor according to the exemplary embodiment. FIG. 11 is a sectional view along line IV-IV in FIG. 3. Thus, FIG. 11 is a sectional view in the same part as FIG. 4.

The structure of the layers below the lower electrode 25 of the photodiode 100 is the same as that of the first exemplary embodiment, and description thereof is omitted. In the upper layer of the lower electrode 25, the photodiode 100 having a three-layer structure in which the n-type semiconductor layer 9, the i-type semiconductor layer 10 and the p-type semiconductor layer 11 are sequentially laminated is formed. Further, the silicide layer 20 is formed on the p-type semiconductor layer 11. The silicide layer 20 is a reaction product layer between a high melting point metal and a semiconductor layer material. The transparent electrode 12 is formed on the silicide layer 20. Thus, the silicide layer 20 is placed between the semiconductor layers constituting the photodiode 100 and the transparent electrode 12. The structure of the layers above the second passivation film 13 is the same as that of the first exemplary embodiment, and description thereof is omitted.

In the TFT substrate included in the photosensor according to the exemplary embodiment, the silicide layer 20 is placed between the transparent electrode 12 and the p-type semiconductor layer 11. This suppresses diffusion of In or the like from the transparent electrode 12 to the p-type semiconductor layer 11. It is thereby possible to suppress reduction of quantum efficiency of the photodiode 100 and achieve a large-size photosensor with a good S/N ratio even at low incident light intensity.

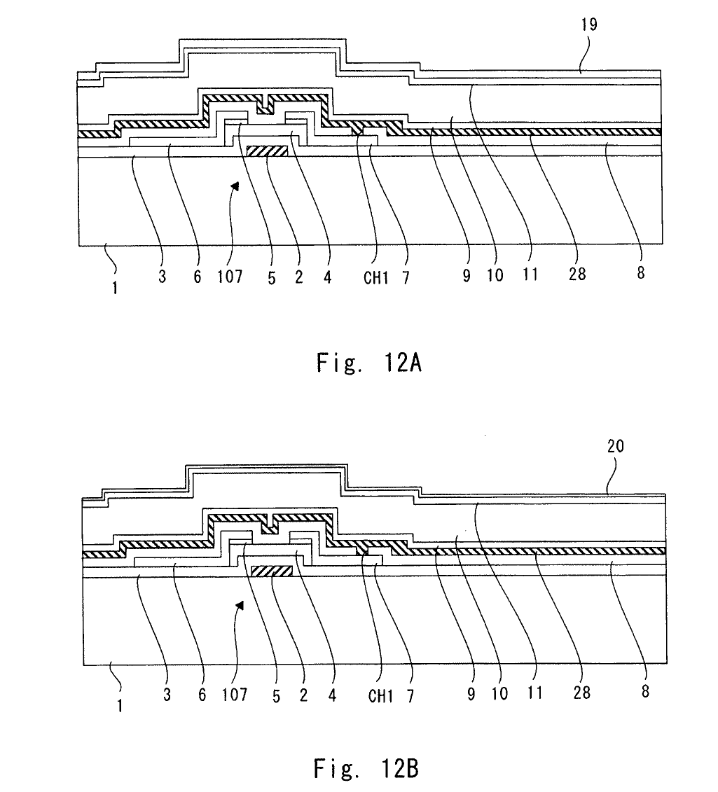

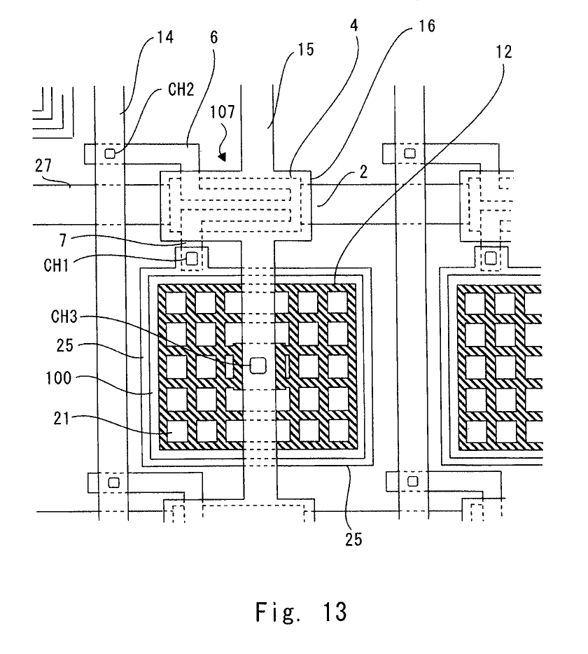

A method of manufacturing the TFT substrate included in the photosensor according to the exemplary embodiment is described hereinafter with reference to FIGS. 12A and 12B. FIGS. 12A and 12B are sectional views showing a manufacturing process of the TFT substrate.

The process up to the deposition of the n-type semiconductor layer 9, the i-type semiconductor layer 10 and the p-type semiconductor layer 11 constituting the photodiode 100 is the same as described in the first exemplary embodiment. Then, a high melting point metal film 19 is deposited on the p-type semiconductor layer 11 by sputtering. As the high melting point metal film 19, a Cr film, for example, is used. The Cr film is deposited with a thickness of 100 nm. By such a process, the structure shown in FIG. 12A is produced.

Then, heat treatment is performed with the p-type semiconductor layer 11 and the high melting point metal film 19 in contact with each other, and the silicide layer 20 is formed between the p-type semiconductor layer 11 and the high melting point metal film 19. A temperature of heat treatment is 250° C., for example. After that, the high melting point metal film 19 is etched away. Etching is performed by wet etching using mixed acid of nitric acid and ceric ammonium nitrate, for example. The silicide layer 20 is thereby exposed to the surface. An etchant is not limited to mixed acid of nitric acid and ceric ammonium nitrate, and another etchant may be used. Further, etching is not limited to wet etching, and dry etching may be used. By such a process, the structure shown in FIG. 12B is produced.

On the silicide layer 20, a transparent conductive film is deposited as a fourth conductive thin film. As the transparent conductive film, an amorphous transparent conductive film is deposited. Then, resist (not shown) is formed by the sixth photolithography process, etched by using oxalic acid, for example, and patterned. The transparent electrode 12 is thereby formed.

Then, resist (not shown) in a photosensitive area of the photodiode 100 is formed on the transparent electrode 12 by the seventh photolithography process. Using the resist as a mask, the silicide layer 20, the n-type semiconductor layer 9, the i-type semiconductor layer 10 and the p-type semiconductor layer 11 are patterned by dry etching. The subsequent manufacturing process is the same as that of the first exemplary embodiment and thus not redundantly described.

Although Cr is used as the high melting point metal film 19 in this exemplary embodiment, a high melting point metal that forms silicide such as W, Ti or Mo may be used instead. Further, heat treatment may be altered depending on a silicide formation process. Furthermore, heat treatment may be eliminated in some cases depending on deposition conditions of the semiconductor layer surface and the high melting point metal film 19.

### Fourth Exemplary Embodiment

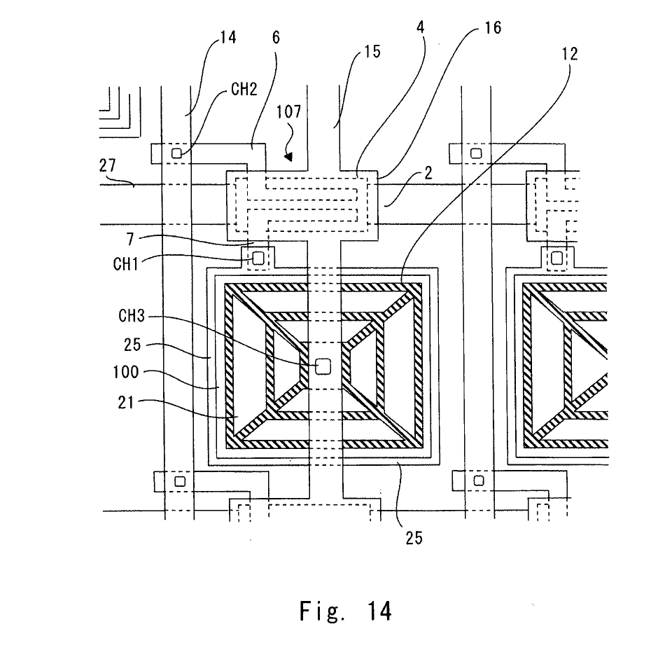

Another exemplary embodiment of the present invention is described hereinafter with reference to the drawings. In this exemplary embodiment, the shape of the transparent electrode 12 is different from that of the first exemplary embodiment. The other structure, manufacturing method or the like is the same as those of the first exemplary embodiment, and description is thus omitted or simplified as appropriate. FIG. 13 is a plan view showing a structure of a pixel of a TFT substrate according to the exemplary embodiment. The cross-sectional structure is substantially the same as that of the above-described embodiments, and only a part related to a planar structure is described hereinbelow.

The transparent electrode 12 formed on the photodiode 100 has openings 21. A plurality of openings 21 exist in the transparent electrode 12 formed in one pixel. In other words, a plurality of openings 21 exist in one pattern of the transparent electrode 12. In an area that is connected to the bias line 15 via the contact hole CH3, a pattern larger than a margin of making the contact hole CH3 is formed. In FIG. 13, the transparent electrode 12 has a rectangular pattern at substantially the center. The contact hole CH3 is made at substantially the center inside the rectangular pattern.

In the other area, the transparent electrode 12 has a mesh-like pattern. Thus, rectangular openings 21 are arranged in an array in the transparent electrode 12. The shape of the transparent electrode 12 is not limited to a mesh. For example, the transparent electrode 12 may have a shape of a spider nest as shown in FIG. 14, or a honeycomb or radial shape. Thus, the openings 21 may have a polygonal shape such as a rectangle or a trapezoid, or a round shape.

In the TFT substrate included in the photosensor according to the exemplary embodiment, the transparent electrode 12 has a plurality of openings 21. By making the openings 21, In or the like can be diffused in the crosswise direction. By providing the area allowing diffusion in the crosswise direction, diffusion in the lengthwise direction can be suppressed. This enables suppression of diffusion of In or the like to the i-type semiconductor layer 10 across the p-type semiconductor layer 11. It is thereby possible to suppress reduction of quantum efficiency of the photodiode 100 and achieve a large-size photosensor with a good S/N ratio even at low incident light intensity. Further, because different wavelength distributions between the transparent electrode 12 and the openings 21 can be set for the incident light to the photodiode 100, it is possible to suppress abrupt deterioration of quantum efficiency due to process variation such as a film thickness.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A photosensor comprising:
a photodiode including a semiconductor layer;
a photodiode electrode made of a transparent conductive film; and
an anti-diffusion layer formed between the semiconductor layer and the photodiode electrode.

2. The photosensor according to claim 1, wherein the anti-diffusion layer is formed in the semiconductor layer on the photodiode electrode side and contains nitrogen or oxygen.

3. The photosensor according to claim 1, wherein the anti-diffusion layer is formed in the photodiode electrode on the semiconductor layer side and contains a higher composition ratio of oxygen than a composition ratio of oxygen at a middle part of the photodiode electrode in a film thickness direction.

4. The photosensor according to claim 1, wherein the anti-diffusion layer is formed in the photodiode electrode on the semiconductor layer side and contains nitrogen.

5. The photosensor according to claim 1, wherein the anti-diffusion layer is formed in the photodiode electrode on the semiconductor layer side and contains a higher composition ratio of zinc than a composition ratio of zinc at a middle part of the photodiode electrode in a film thickness direction.

6. The photosensor according to claim 1, wherein the anti-diffusion layer is a silicide layer.

7. The photosensor according to claim 1, wherein the photodiode electrode has a plurality of openings in one pattern.

8. The photosensor according to claim 1, further comprising:
a thin film transistor that is electrically connected to the photodiode;
a data line that is electrically connected to a source electrode of the thin film transistor;
a reading circuit that is electrically connected to the data line and reads charge from the data line;
a digital circuit that is electrically connected to the reading circuit and at least includes an A/D converter; and
a gate driving circuit that is electrically connected to a gate electrode of the thin film transistor and drives the thin film transistor.

9. The photosensor according to claim 1, further comprising:
a scintillator that is formed on a light incident side of the photodiode.

10. A method of manufacturing a photosensor comprising steps of:
depositing a semiconductor layer constituting a photodiode; and
depositing a transparent conductive film used for forming a photodiode electrode placed opposite to the semiconductor layer with an anti-diffusion layer interposed therebetween.

11. The method of manufacturing a photosensor according to claim 10, wherein
in the step of depositing the semiconductor layer, the anti-diffusion layer is formed in an upper layer of the semiconductor layer by performing deposition with addition of gas containing nitrogen at a late stage of depositing the semiconductor layer, and
in the step of depositing the transparent conductive film, the transparent conductive film is deposited on the anti-diffusion layer.

12. The method of manufacturing a photosensor according to claim 10, further comprising:
a step of forming the anti-diffusion layer in an upper layer of the semiconductor layer by performing surface treatment of the deposited semiconductor layer in an atmosphere containing nitrogen plasma or oxygen plasma after the step of depositing the semiconductor layer,
wherein in the step of depositing the transparent conductive film, the transparent conductive film is deposited on the anti-diffusion layer.

13. The method of manufacturing a photosensor according to claim 12, wherein the step of depositing the semiconductor layer and the step of forming the anti-diffusion layer are performed in one device.

14. The method of manufacturing a photosensor according to claim 10, further comprising:
a step of forming the anti-diffusion layer by forming a silicide layer on the semiconductor layer after the step of depositing the semiconductor layer,
wherein in the step of depositing the transparent conductive film, the transparent conductive film is deposited on the anti-diffusion layer.

15. The method of manufacturing a photosensor according to claim 10, wherein in the step of depositing the transparent conductive film, the anti-diffusion layer is formed in a lower layer of the transparent conductive film by performing deposition with addition of gas containing nitrogen at an initial stage of deposition on the semiconductor layer.

16. The method of manufacturing a photosensor according to claim 10, wherein in the step of depositing the transparent conductive film, the anti-diffusion layer is formed in a lower layer of the transparent conductive film by performing deposition with use of a higher oxygen flow at an initial stage of deposition than at an intermediate stage of deposition on the semiconductor layer.

17. The method of manufacturing a photosensor according to claim 10, wherein in the step of depositing the transparent conductive film, the anti-diffusion layer is formed in a lower layer of the transparent conductive film by performing deposition with use of a material having a larger content of zinc at an initial stage of deposition than at an intermediate stage of deposition on the semiconductor layer.
